(19) United States
(12) Patent Application Publication
(10) Pub. No.: US 2011/0240086 A1
(43) Pub. Date: Oct. 6, 2011

(54) PHOTOELECTRIC CONVERSION DEVICE AND PHOTOELECTRIC CONVERSION DEVICE MODULE

(75) Inventors: Masahiro Morooka, Kanagawa (JP); Keishi Tada, Kanagawa (JP)

(73) Assignee: Sony Corporation, Tokyo (JP)

(21) Appl. No.: 13/053,603

(22) Filed: Mar. 22, 2011

(30) Foreign Application Priority Data
Mar. 31, 2010 (JP) 2010-080220

(51) Int. Cl. H01L 31/042; H01L 31/0224; H01L 51/44

(52) U.S. Cl. 136/244; 136/256

(57) ABSTRACT

The present invention is to provide a photoelectric conversion device including: a first substrate; a collector layer configured to be provided over the first substrate; a second substrate configured to be opposed to a planar surface of the first substrate and be formed of a metal having a concave notch part at one side; and a connection terminal configured to be connected to the collector layer. The connection terminal is disposed opposed to the concave notch part.

### BACKGROUND OF THE INVENTION

1. Field of the Invention

The present invention relates to a photoelectric conversion device and a photoelectric conversion device module obtained by disposing the photoelectric conversion devices in a plane and connecting them to each other.

2. Description of the Related Art

In recent years, awareness of environmental protection is increasing and the importance of photovoltaic power generation is further increasing. In the dye-sensitized solar cell (DSSC), a transparent electrically-conductive layer and an oxide semiconductor layer are formed over a transparent substrate, and a dye-carrying oxide semiconductor layer (photoelectric conversion layer) obtained by making this oxide semiconductor layer carry a sensitizing dye is used as the working electrode (photoelectrode, window electrode). In addition, a redox electrolyte layer is disposed between this working electrode and the opposing electrode. In this dye-sensitized solar cell, electrons excited in the dye by sunlight are injected into the oxide semiconductor layer to flow to the transparent electrically-conductive film and a current flows to the opposing electrode via an external circuit including a load, so that operation as a cell is obtained.

The dye-sensitized solar cell is advantageous over the silicon-based solar cell in that constraints in terms of resources on the raw materials necessary for manufacturing are less, and in that it does not require vacuum equipment and can be manufactured by a printing system or a flow production system and thus the manufacturing cost and the facility cost are lower.

In such a dye-sensitized solar cell, increase in the light reception area and higher photoelectron quantum conversion efficiency are desired. However, because the resistance of the transparent electrically-conductive layer of e.g. ITO or FTO is high, it is difficult to avoid the lowering of the conversion efficiency accompanying the area increase. As a countermeasure thereagainst, e.g. a method of providing a collector interconnect on the surface of the transparent electrically-conductive layer to thereby decrease the resistance is employed.

As the dye-sensitized solar cell, solar cells having various kinds of structures have been proposed. For example, there are several reports on a dye-sensitized solar cell having a structure in which a working electrode (photoelectrode, window electrode) formed of a dye-carrying oxide semiconductor layer (photoelectric conversion layer) obtained by making an oxide semiconductor such as titanium dioxide carry a sensitizing dye and a collector interconnect layer (collector electrode) provided with a protective layer are formed over a transparent substrate on which a transparent electrically-conductive layer of e.g. ITO or FTO is formed and a redox electrolyte layer is disposed between this working electrode and an opposing electrode opposed to the working electrode (refer to e.g. Japanese Patent Laid-open No. 2005-142089 (paragraphs 0056 and 0057, FIG. 1), Japanese Patent Laid-open No. 2006-92854 (paragraphs 0022 to 0025, FIG. 1), Japanese Patent Laid-open No. 2007-280906 (paragraphs 0033 to 0037, FIG. 1), and Japanese Patent Laid-open No. 2009-277624 (paragraphs 0015 to 0017, paragraph 0042, FIG. 1, FIG. 3) (hereinafter, Patent Document 1, Patent Document 2, Patent Document 3 and Patent Document 4, respectively)).

Furthermore, there are several reports on a dye-sensitized solar cell having a structure in which the distance between the working electrode and the opposing electrode is shortened (refer to e.g. Japanese Patent Laid-open No. 2005-346971 (paragraphs 0006 to 0019, FIG. 1) and Japanese Patent Laid-open No. 2009-9866 (paragraphs 0015 to 0020, FIG. 1), (hereinafter, Patent Document 5 and Patent Document 6, respectively)).

There are several reports on the connection structure between solar battery cells in a solar cell module formed by disposing plural solar battery cells in a plane and electrically connecting them to each other (refer to e.g. Japanese Patent Laid-open No. 2006-244954 (paragraphs 0010 to 0032, FIG. 1 to FIG. 6) and Japanese Patent Laid-open No. 2008-226554 (paragraphs 0033 to 0060, FIG. 1 to FIG. 5), (hereinafter, Patent Document 7 and Patent Document 8, respectively)).

The dye-carrying oxide semiconductor layer (photoelectric conversion layer) in the dye-sensitized solar cell as a photoelectric conversion device is so provided as the working electrode as to cover the transparent electrically-conductive layer formed on the transparent substrate such as a glass substrate in many cases. However, because the transparent electrically-conductive layer is required to have transparency, decreasing its resistance is subjected to certain constraints. Therefore, as the area of the dye-sensitized solar cell becomes larger, it becomes more difficult to effectively collect electrons arising from photoelectric conversion by the photoelectric conversion layer. As a countermeasure thereagainst, for example a low-resistance collector interconnect layer (collector electrode) in a grid manner is formed on the transparent electrically-conductive layer so that current may be collected into this collector electrode.

To reduce resistive loss by the transparent electrically-conductive layer and decrease the resistance, the width or thickness of the collector electrode needs to be increased. However, for example if the width is increased, the area of the photoelectric conversion layer decreases and the conversion efficiency per unit area is lowered. If the thickness of the collector electrode is increased, the distance between the working electrode and the opposing electrode opposed to the working electrode, i.e. the thickness of the electrolyte layer, increases and thus the transfer velocity of ions is lowered. As a result, the lowering of the conversion efficiency is caused due to resistive loss by the electrolyte layer.

Although the resistive loss by the transparent electrically-conductive layer can be reduced by the provision of the collector electrode, it is preferable to dispose the collector interconnect under such an optimum condition as to minimize the resistive loss. In addition, to reduce the resistive loss by the electrolyte layer, the distance between the working electrode and the opposing electrode needs to be set as short as possible and a suitable structure needs to be devised.

Although dye-sensitized solar cells having a structure in which the distance between the working electrode and the opposing electrode is shortened have been reported in Patent Document 5 and Patent Document 6, this structure is complex.

In the case of forming a solar cell module by disposing plural dye-sensitized solar cells (solar battery cells) in a plane and electrically connecting the solar battery cells to each other, it is required to obtain a solar cell module having enhanced light collection efficiency by setting a small area as the area of the terminal area for electrically connecting the solar battery cells to each other and setting a large area as the light reception area of each solar battery cell to thereby set the light reception area by the whole of the solar battery cells as large as possible relative to the whole placement area of the solar cell module. Furthermore, the connection structure by which the solar battery cells are easily electrically connected to each other is required. However, in the solar cell modules described in Patent Document 7 and Patent Document 8, sufficient considerations for these requirements are not made.

### SUMMARY OF THE INVENTION

There is a desire for the present invention to provide a photoelectric conversion device that has a simple structure and allows enhancement in the conversion efficiency and easy mutual connection, and a photoelectric conversion device module that is obtained by disposing the photoelectric conversion devices in a plane and connecting them to each other and has enhanced light collection efficiency.

According to a first embodiment of the present invention, there is provided a photoelectric conversion device including a first substrate (e.g. transparent substrate 1 in an embodiment of the present invention to be described later), a collector layer (e.g. collector grid 3 in the embodiment to be described later) configured to be provided over the first substrate, a second substrate (e.g. opposing substrate 9 in the embodiment to be described later) configured to be opposed to a planar surface of the first substrate and be formed of a metal having a concave notch part at one side, and a connection terminal configured to be connected to the collector layer. The connection terminal is disposed opposed to the concave notch part.

According to a second embodiment of the present invention, there is provided a photoelectric conversion device module including a plurality of the above-described photoelectric conversion devices configured to be disposed in a plane. The connection terminal of one of two photoelectric conversion devices adjacent to each other and the second substrate of the other are electrically connected to each other.

According to the first embodiment of the present invention, the photoelectric conversion device has the first substrate, the collector layer provided over this first substrate, the second substrate that is opposed to the planar surface of the first substrate and is formed of a metal having the concave notch part at one side, and the connection terminal connected to the collector layer, and the connection terminal is disposed opposed to the concave notch part. Therefore, the photoelectric conversion device has a simple structure and allows increase in the thickness of the collector layer and enhancement in the current collection efficiency. Furthermore, it is possible to provide such a photoelectric conversion device that the plural photoelectric conversion devices can be disposed in a plane in substantially close to each other and be easily mutually connected.

According to the second embodiment of the present invention, a plurality of the above-described photoelectric conversion devices are disposed in a plane, and the connection terminal of one of two photoelectric conversion devices adjacent to each other and the second substrate of the other are electrically connected to each other. Therefore, the plural photoelectric conversion devices that have a simple structure and allow enhancement in the conversion efficiency can be disposed in a plane in substantially close to each other and be easily mutually connected, and it is possible to provide a photoelectric conversion device module having an increased ratio of the light reception area to the total area of the arrangement of the plural photoelectric conversion devices and enhanced light collection efficiency.

### BRIEF DESCRIPTION OF THE DRAWINGS

FIG. 1 is a plan view for explaining the configuration of a dye-sensitized solar cell (opposed cell) in an embodiment of the present invention;

FIGS. 2A to 2D are sectional views for explaining the configuration of the dye-sensitized solar cell (opposed cell) in the embodiment;

FIGS. 3A and 3B are diagrams made by projecting the patterns of the respective layers configuring the dye-sensitized solar cell (opposed cell) onto substrates in the embodiment;

FIG. 4 is a plan view for explaining an arrangement of the dye-sensitized solar cells (opposed cells) in the embodiment;

FIGS. 5A to 5D are sectional views for explaining mounting and connecting of the dye-sensitized solar cells (opposed cells) in the embodiment;

FIGS. 6A to 6C are sectional views for explaining the configuration of the dye-sensitized solar cell (opposed cell) in the embodiment;

FIGS. 7A and 7B are sectional views for explaining the electron flow direction in the dye-sensitized solar cell (opposed cell) in the embodiment;

FIG. 8 is a diagram for explaining the pattern of a porous photoelectric conversion layer (TiO₂ electrode) in a working example of the present invention;

FIG. 9 is a diagram for explaining the pattern of a catalyst layer (carbon electrode) in the working example;

FIG. 10 is a diagram for explaining the pattern of a collector grid (Ag electrode) in the working example;

FIG. 11 is a diagram for explaining the pattern of a protective layer (Ag-electrode protecting layer) in the working example;

FIG. 12 is a diagram for explaining the pattern of a sealant layer in the working example;

FIGS. 13A and 13B are diagrams for explaining the shape of an opposing substrate in the working example;

FIGS. 14A to 14C are sectional views for explaining the relationship between an opposed cell and its unit structure and derivation of the optimum electrode width in the working example; and

FIGS. 15A and 15B are diagrams for explaining the optimum electrode width in the working example.

### DETAILED DESCRIPTION OF THE PREFERRED EMBODIMENT

It is preferable for the photoelectric conversion device according to the first embodiment of the present invention to have the following configuration. Specifically, the photoelectric conversion device further includes a transparent electrically-conductive layer configured to be formed on the first substrate, an oxide semiconductor layer configured to be formed on a surface of the transparent electrically-conductive layer in a strip manner on a plurality of columns and carry a dye, a protective layer configured to cover the surface of the collector layer, a catalyst layer configured to be formed over the second substrate, and an electrolyte layer configured to be formed between the first substrate and the second substrate. The second substrate has a continuous flat surface opposed to the planar surface of the first substrate. The collector layer is formed on the surface of the transparent electrically-conductive layer in a line manner on a plurality of columns in such a manner as to sandwich the oxide semiconductor layer. The catalyst layer is continuously or discontinuously formed over the flat surface. The oxide semiconductor layer and the catalyst layer are disposed opposed to each other. The tip of the protective layer is disposed at a position between a surface of the catalyst layer and the flat surface.

That is, it is preferable for the photoelectric conversion device to have the following configuration. Specifically, the photoelectric conversion device has the first substrate on which the transparent electrically-conductive layer is formed, the oxide semiconductor layer that is formed on the surface of the transparent electrically-conductive layer in a strip manner on a plurality of columns and carries a dye, the collector layer formed on the surface of the transparent electrically-conductive layer in a line manner on a plurality of columns in such a manner as to sandwich this oxide semiconductor layer, and the protective layer covering the surface of this collector layer. The photoelectric conversion device further includes the connection terminal connected to the collector layer, the second substrate that has the continuous flat surface opposed to the planar surface of the first substrate and has the concave notch part at one side, the catalyst layer continuously or discontinuously formed over the flat surface, and the electrolyte layer formed between the first substrate and the second substrate. The oxide semiconductor layer and the catalyst layer are disposed opposed to each other. The tip of the protective layer is disposed at a position between the surface of the catalyst layer and the flat surface. The connection terminal is disposed opposed to the concave notch part.

According to such a configuration, the photoelectric conversion device has a simple structure and allows increase in the thickness of the collector layer and enhancement in the current collection efficiency. Furthermore, the distance between the oxide semiconductor layer and the catalyst layer can be set short. Thus, the conversion efficiency can be enhanced even when an electrolytic liquid having high resistance is used for the electrolyte layer. Moreover, the photoelectric conversion device allowed to have enhanced conversion efficiency can be provided by disposing the collector interconnect under such an optimum condition as to minimize resistive loss by the transparent electrically-conductive layer.

Furthermore, it is preferable to employ a configuration in which H>(Hₜ+H_{c}) and H>Hₚ>(Hₜ+g) are satisfied when H is the distance between the surface of the transparent electrically-conductive layer and the flat surface, Hₜ is the thickness of the oxide semiconductor layer, H_{c} is the thickness of the catalyst layer, Hₚ is the distance between the surface of the transparent electrically-conductive layer and the tip of the protective layer, and g is the interval between opposed surfaces of the oxide semiconductor layer and the catalyst layer. Such a configuration can provide the photoelectric conversion device in which the oxide semiconductor layer and the catalyst layer can be disposed close to each other and thus the lowering of the conversion efficiency occurring due to resistive loss by the electrolyte layer can be suppressed, and the lowering of the conversion efficiency due to the contact of the oxide semiconductor layer with the catalyst layer can be suppressed. The thickness Hₜ of the oxide semiconductor layer is the distance between the average surfaces obtained by averaging concave and convex of the transparent electrically-conductive layer and the oxide semiconductor layer. The thickness H_{c} of the catalyst layer is the distance between the average surfaces obtained by averaging concave and convex of the second substrate and the catalyst layer. The interval g between the oxide semiconductor layer and the catalyst layer is the distance between the average surfaces obtained by averaging concave and convex of the oxide semiconductor layer and the catalyst layer.

In addition, it is preferable to employ a configuration in which the catalyst layer is continuously formed and a concave part that accepts the tip of the protective layer is formed in the catalyst layer, and the tip of the protective layer is disposed in the inside of the concave part. In such a configuration, the catalyst layer is in contact with the electrolyte layer across its whole surface. This can provide the photoelectric conversion device in which reduction reaction of oxidized redox ions is promoted and the conversion efficiency can be enhanced.

Moreover, it is preferable to employ a configuration in which W_{c}≧Wₚ is satisfied when Wₚ is the external width of the protective layer and W_{c} is the width of the inside of the concave part. Such a configuration can provide the photoelectric conversion device in which the break of the protective layer due to the contact of the protective layer with the catalyst layer can be suppressed and the collector layer can be surely protected by the protective layer, and the lowering of the conversion efficiency can be suppressed.

Furthermore, it is preferable to employ a configuration in which the catalyst layer is discontinuously formed in a strip manner on a plurality of columns and the tip of the protective layer is located between the catalyst layers that are adjacent to each other and are in the strip manner. Such a configuration can provide the photoelectric conversion device in which the oxide semiconductor layer and the catalyst layer can be disposed close to each other and the lowering of the conversion efficiency occurring due to resistive loss by the electrolyte layer can be suppressed.

In addition, it is preferable to employ a configuration in which W_{c}≧Wₚ is satisfied when Wₚ is the external width of the protective layer and W_{c} is the distance between the catalyst layers adjacent to each other. Such a configuration can provide the photoelectric conversion device in which the break of the protective layer due to the contact of the protective layer with the catalyst layer can be suppressed and the collector layer can be surely protected by the protective layer, and the lowering of the conversion efficiency can be suppressed.

Moreover, it is preferable to employ a configuration in which the width of the oxide semiconductor layer is so decided that a value obtained by subtracting power loss due to resistive loss occurring in the whole of the oxide semiconductor layer from generated power arising in the whole of the oxide semiconductor layer is maximized. In such a configuration, the width of the oxide semiconductor layer is so decided that the contribution of power loss due to resistive loss occurring in the whole of the oxide semiconductor layer is minimized. This can provide the photoelectric conversion device in which the lowering of the conversion efficiency occurring due to resistive loss by the oxide semiconductor layer can be suppressed.

The photoelectric conversion device according to the embodiment of the present invention has a transparent substrate on which a transparent electrically-conductive film is formed, a porous photoelectric conversion layer that is formed on a surface of the transparent electrically-conductive film in a strip manner on plural columns and carries a dye. The photoelectric conversion device further has a collector grid that is formed on the surface of the transparent electrically-conductive film in a line manner on plural columns in such a manner as to sandwich this porous photoelectric conversion layer and is covered by a protective layer, and an opposing substrate that is disposed opposed to the transparent substrate and is formed of a metal in which a concave notch part is formed at one side. In addition, the photoelectric conversion device further has, over a surface of this opposing substrate, a catalyst layer that is continuously formed and has a concave part that accepts the tip of the protective layer or a catalyst layer that is discontinuously formed in a strip manner on plural columns. Moreover, the photoelectric conversion device further has an electrolyte layer formed between the transparent substrate and the opposing substrate. It is also possible to employ the following configuration. Specifically, the concave notch part is not formed in the opposing substrate and an aperture part made by opening a penetrating hole is formed near a side of the opposing substrate. Furthermore, the connection terminal connected to the collector grid is disposed opposed to this aperture part.

The porous photoelectric conversion layer and the catalyst layer are disposed opposed to each other, and the tip of the protective layer is disposed in the inside of the concave part or disposed opposed to the opposing substrate between adjacent catalyst layers. By such a simple structure, the distance between the porous photoelectric conversion layer and the catalyst layer can be set short and resistive loss by the electrolyte layer can be reduced to enhance the conversion efficiency. Furthermore, the connection terminal connected to the collector grid and the concave notch part are disposed opposed to each other. By such a simple structure, the distance between the photoelectric conversion layer and the catalyst layer can be set short and resistive loss by the electrolyte layer can be reduced to enhance the conversion efficiency. In addition, the photoelectric conversion device has a shape suitable for integration into a module.

An embodiment of the present invention will be described in detail below with reference to the drawings by taking a dye-sensitized solar cell as an example of the photoelectric conversion device. However, the present invention is not limited to this embodiment as long as the configuration satisfies the above-described operation and effects. It should be noted that the drawings shown below are so made as to allow clear, easy understanding of the configurations and therefore the scales of the drawings are not strictly accurate.

### Embodiment

### Opposed Cell

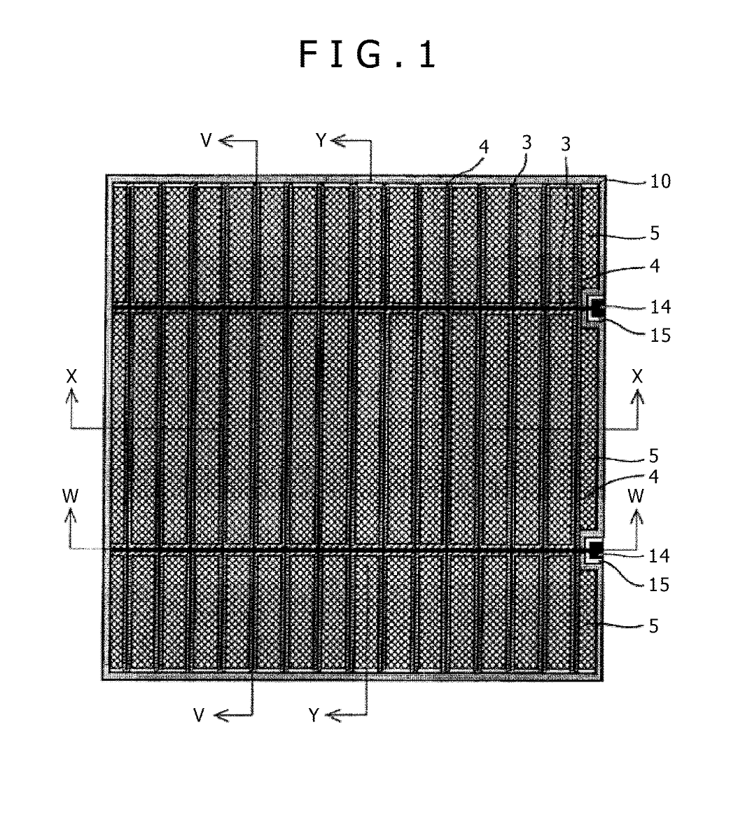

FIG. 1 is a plan view for explaining the configuration of a dye-sensitized solar cell (opposed cell) in the embodiment of the present invention.

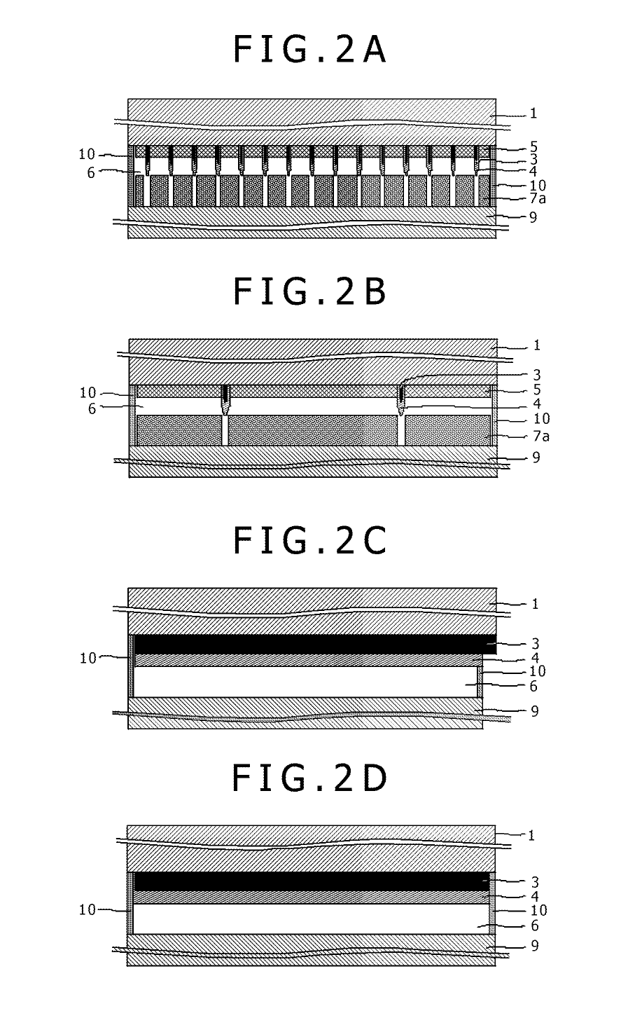

FIGS. 2A to 2D are sectional views for explaining the configuration of the dye-sensitized solar cell (opposed cell) in the embodiment of the present invention.

FIG. 2A is a sectional view along line X-X shown in FIG. 1 (X-X sectional view). FIG. 2B is a sectional view along line Y-Y shown in FIG. 1 (Y-Y sectional view). FIG. 2C is a sectional view along line W-W shown in FIG. 1 (W-W sectional view). FIG. 2D is a sectional view along line V-V shown in FIG. 1 (V-V sectional view).

As shown in FIG. 1 and FIGS. 2A to 2D, the opposed cell is composed of a window electrode (working electrode) on which light is incident, a counter electrode disposed opposed to the window electrode, and an electrolyte layer 6 disposed between the window electrode (working electrode) and the counter electrode. The window electrode (working electrode) is composed of a transparent substrate 1, a transparent electrically-conductive film 2, a collector grid 3, a protective layer 4, and a porous photoelectric conversion layer 5. The counter electrode is composed of a catalyst layer 7a, an opposing substrate 9 formed of a metal, and a sealant layer 10.

In the opposed cell, the electrolyte layer 6 is disposed between the transparent electrically-conductive film 2 on which the porous photoelectric conversion layer 5 is pattern-formed into a strip shape (this transparent electrically-conductive film 2 is formed on a surface of the transparent substrate 1) and an opposing electrode 8 on which the catalyst layer 7a is pattern-formed into a strip shape (this opposing electrode 8 is formed on a surface of the opposing substrate 9), and plural photoelectric conversion elements are formed. Between adjacent photoelectric conversion elements, the collector grid 3 that is covered by the protective layer 4 and serves as an interconnect for current collection is formed. One photoelectric conversion element is formed with the porous photoelectric conversion layer 5, the electrolyte layer 6, and the catalyst layer 7a stacked between the window electrode (working electrode) and the counter electrode.

In the opposed cell, each of the photoelectric conversion elements separated by the collector grid 3 covered by the protective layer 4 is formed between the transparent electrically-conductive film 2 of the window electrode (working electrode) and the opposing electrode 8 of the counter electrode, and each photoelectric conversion element is electrically connected to two adjacent collector grids 3.

A concave notch part 15 is formed at one side of the opposing substrate 9 so that a connection terminal 14 may be exposed to the external.

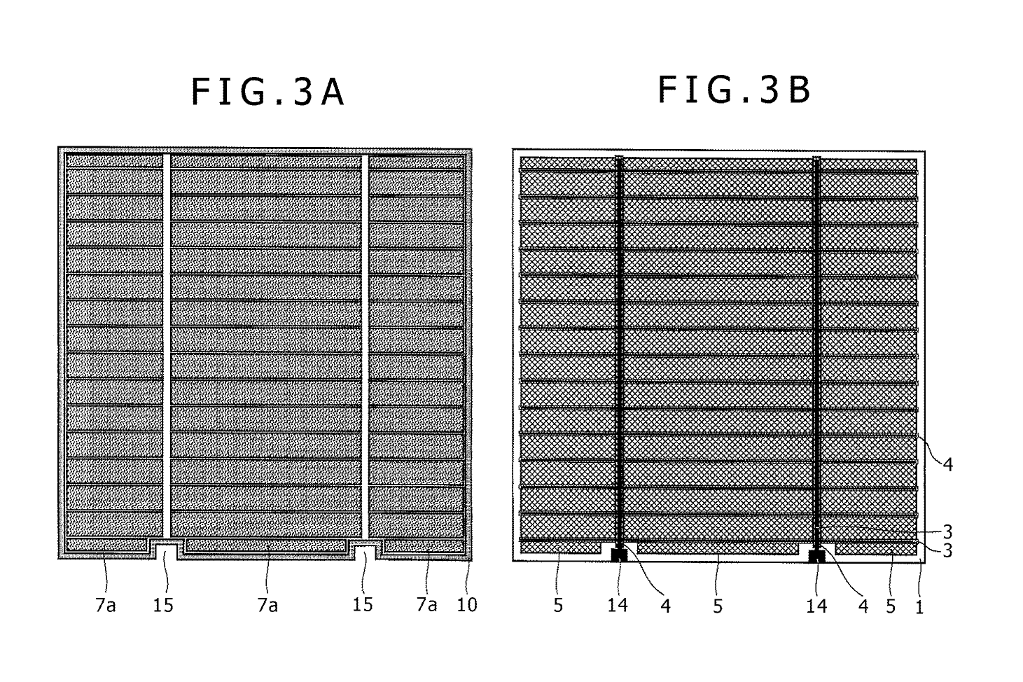

FIGS. 3A and 3B are diagrams made by projecting, onto the substrates, the patterns of the respective layers configuring the dye-sensitized solar cell (opposed cell) in the embodiment of the present invention.

FIG. 3A is a diagram made by projecting the patterns of the porous photoelectric conversion layer (e.g. TiO₂ electrode) 5, the collector grid (e.g. Ag electrode) 3 serving as the interconnect for current collection, and the protective layer (Ag-electrode protecting layer) 4 onto the transparent substrate (transparent glass substrate (e.g. FTO glass substrate on which FTO is formed)) 1. FIG. 3B is a diagram made by projecting the patterns of the catalyst layer (e.g. carbon electrode) 7a and the sealant layer 10 onto the opposing substrate (e.g. titanium plate) 9.

As shown in FIG. 1 to FIG. 3B, each of the porous photoelectric conversion layer 5 and the catalyst layer 7a is formed in a strip manner on plural columns and rows (in the example shown in FIGS. 3A and 3B, sixteen columns and three rows). Each of the collector grid 3 and the protective layer 4 has a narrow width and is formed in a line manner on plural columns and rows (in the example shown in FIGS. 3A and 3B, fifteen columns and two rows). The collector grid 3 formed in a line manner is connected to the connection terminal 14 formed near one side of the transparent substrate 1. This connection terminal 14 is formed at the position that corresponds to the concave notch part 15 formed in the opposing substrate 9 when the transparent substrate 1 is bonded to the opposing substrate 9 by the sealant layer 10. The connection terminal 14 is exposed to the external.

The window electrode (working electrode) on which light is incident and the counter electrode disposed opposed to it are fabricated in the following manner.

The window electrode (working electrode) on which light is incident is fabricated in the following manner. A transparent electrically-conductive substrate obtained by forming a transparent electrically-conductive film on the transparent substrate 1 is used as a window electrode (working electrode) substrate. Part of the transparent electrically-conductive film at the outer circumference of this transparent electrically-conductive substrate (bonded to the sealant layer 10) is removed.

First, a porous oxide semiconductor layer is formed on the transparent electrically-conductive film 2. Next, the collector grid 3 is formed on a surface of the transparent electrically-conductive film 2. Furthermore, the protective layer 4 to shield and protect the collector grid 3 from the electrolyte layer 6 is formed. Next, the porous photoelectric conversion layer 5 is formed by making the porous oxide semiconductor layer previously formed carry a sensitizing dye.

The counter electrode opposed to the window electrode (working electrode) is fabricated in the following manner. The catalyst layer 7a is formed on a surface of the opposing substrate 9 formed of a metal serving also as the opposing electrode. Next, an electrolytic liquid pouring inlet is formed at a predetermined position of the opposing substrate 9. Next, the sealant layer 10 is formed on the surface of the opposing substrate 9.

The electrode surfaces of the window electrode (working electrode) and the counter electrode prepared in the following manner are set opposed to each other in such a manner as to sandwich the sealant layer 10 and the sealant is cured to render the window electrode (working electrode) and the counter electrode monolithic with each other.

Next, e.g. an electrolytic liquid is injected from the electrolytic liquid pouring inlet (not shown) previously formed in the opposing substrate 9 and is made to permeate the inside of the opposed cell. Thereafter, the electrolytic liquid around the pouring inlet is removed and the electrolytic liquid pouring inlet is sealed.

If the opposed cell shown in FIG. 1 to FIG. 3B is used solely, the respective collector grids 3 formed in a line manner are connected and an interconnect connected to an external load is made on each of the connection terminal 14, which is formed near one side of the transparent substrate 1 and exposed to the external, and the back surface of the opposing substrate 9.

### <Example of Mounting and Connecting of Plural Opposed Cells>

A solar cell module in which plural opposed cells shown in FIG. 1 to FIG. 3B are used is formed in the following manner.

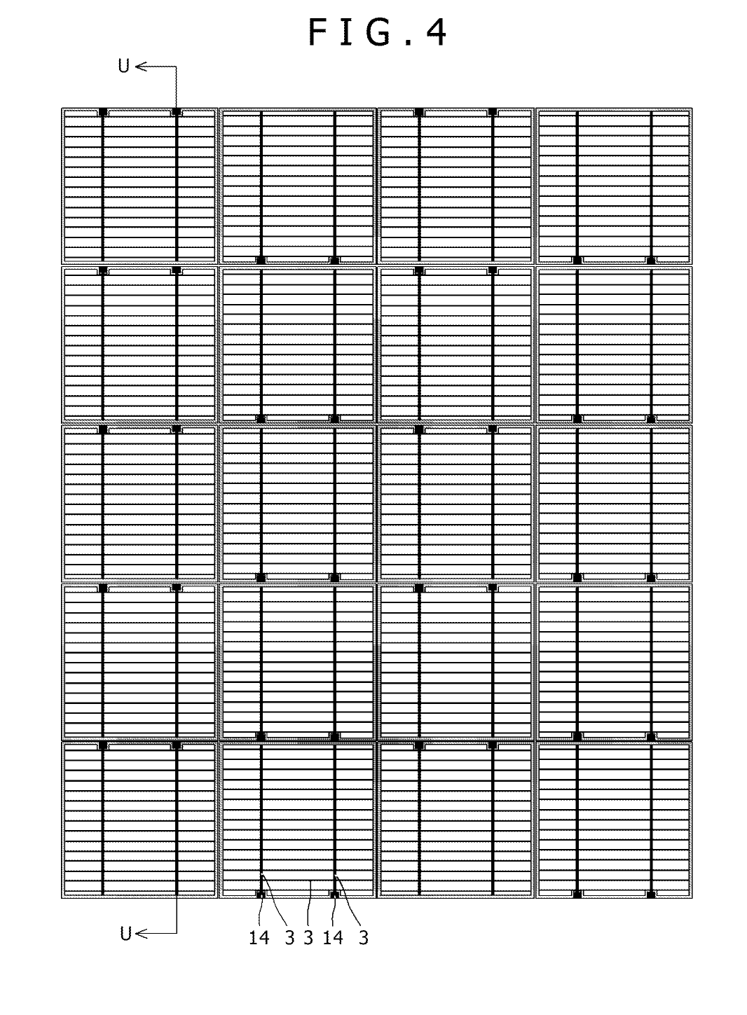

FIG. 4 is a plan view for explaining the arrangement of the dye-sensitized solar cells (opposed cells) in the embodiment of the present invention.

As shown in FIG. 4, the solar cell module has a structure based on series connection of the whole of plural opposed cells arranged in a matrix. This structure is made as follows. Specifically, a cell unit is formed by disposing plural opposed cells shown in FIG. 1 to FIG. 3B along the vertical direction in a straight line manner with the intermediary of gaps and electrically connecting them to each other. Plural cell units are disposed along the horizontal direction. In addition, in each cell unit, the opposed cells adjacent to each other along the vertical direction are electrically connected in series to each other by a solder-plated interconnect member (interconnector). Furthermore, electrical series connection between the cell units is made.

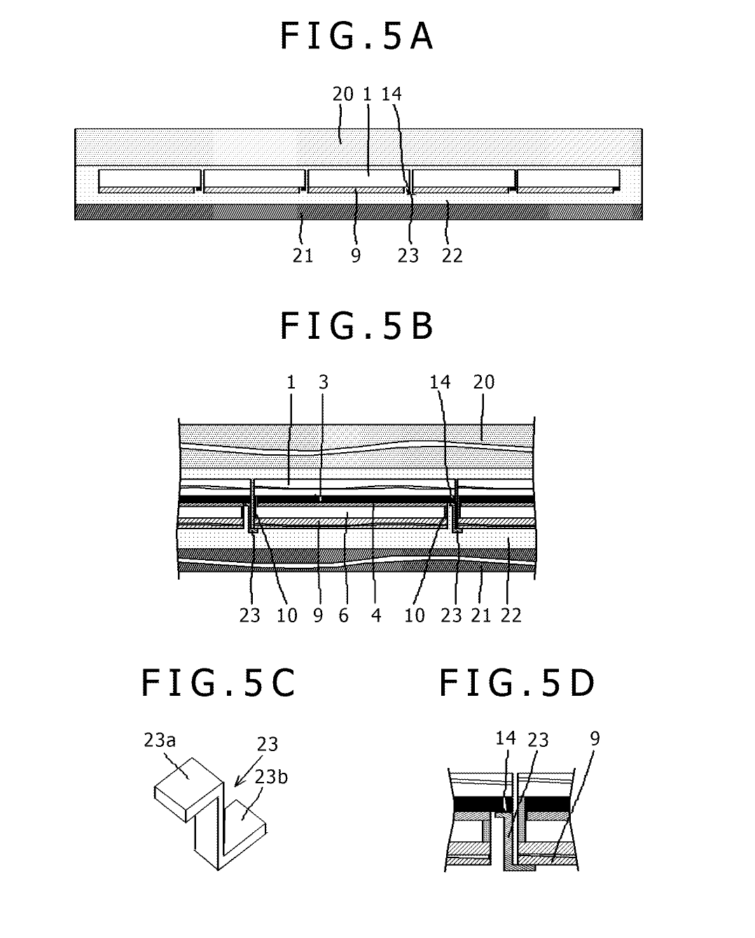

FIGS. 5A to 5C are diagrams for explaining mounting and connecting of the plural dye-sensitized solar cells (opposed cells) in the embodiment of the present invention.

FIG. 5A is a sectional view along line U-U shown in FIG. 4 (corresponding to line W-W shown in FIG. 1) (U-U sectional view). FIG. 5B is a detailed partially enlarged view of FIG. 5A. FIG. 5C is a perspective view for explaining an example of the shape of the interconnector and its connection surfaces. FIG. 5D is a locally enlarged sectional view of a connection part by the interconnector.

As shown in FIG. 5A, the solar cell module is made by sealing the plural opposed cells arranged in a matrix shown in FIG. 4 between a transparent support upper plate (upper cover sheet) 20 and a support lower plate (lower cover sheet) 21 by using a transparent filler 22 such as an ethylene-vinyl acetate (EVA) copolymer resin. Adjacent opposed cells are disposed with the intermediary of a gap so that the opposing substrates 9 of the adjacent opposed cells may be prevented from getting contact with each other. The adjacent opposed cells are electrically connected to each other by an interconnector 23. The gap between the adjacent opposed cells is not particularly limited and is normally equal to or longer than 0.5 mm. The shorter this gap is, the higher the light-use efficiency is higher. However, if the gap is shorter than 0.5 mm, in sealing of the plural opposed cells, possibly adjacent opposed cells get contact with each other and are broken.

As shown in FIG. 5B to FIG. 5D, in adjacent opposed cells, the connection terminal 14 formed on the transparent substrate 1 of one opposed cell and the opposing substrate 9 of the other opposed cell are electrically connected to each other by the interconnector 23. In this interconnector 23, at almost the center thereof, a flexure step part corresponding to the thickness of the opposed cell from which the thickness of the transparent substrate 1 is subtracted is formed. Via this flexure step part, one connection surface A (23a) is connected to the connection terminal 14 of one opposed cell and the other connection surface B (23b) is connected to the opposing substrate 9 of the other opposed cell.

### <Configuration of Opposed Cell>

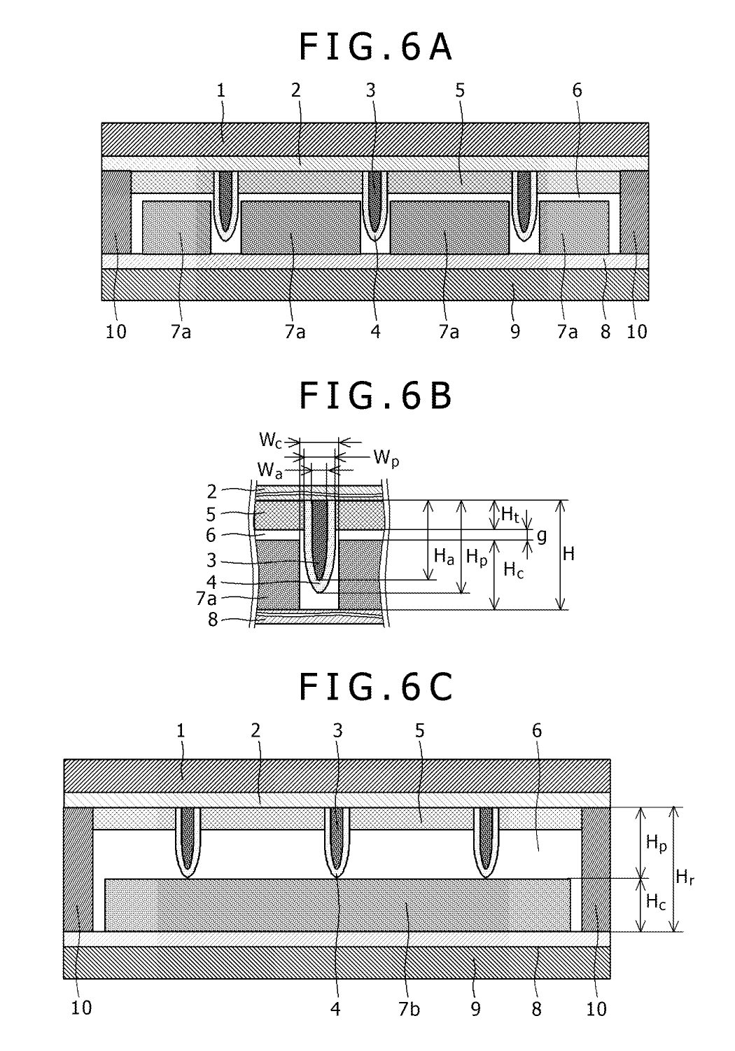

FIGS. 6A to 6C are sectional views for explaining the configuration of the dye-sensitized solar cell (opposed cell) in the embodiment of the present invention.

FIG. 6A is a diagram for explaining a configuration in which the catalyst layer 7a having a rectangular shape is disposed on the opposing electrode 8. FIG. 6B is a partially enlarged view of FIG. 6A. FIG. 6C is a diagram for explaining the positional relationship between the opposing electrode 8 and a catalyst layer 7b in a comparative example.

As shown in FIG. 6A and FIG. 6B, in the opposed cell, the electrolyte layer 6 is disposed between the transparent electrically-conductive film 2 on which the porous photoelectric conversion layer 5 is pattern-formed into a strip shape (this transparent electrically-conductive film 2 is formed on a surface of the transparent substrate 1) and the opposing electrode 8 on which the catalyst layer 7a is pattern-formed into a strip shape (this opposing electrode 8 is formed on a surface of the opposing substrate 9), and plural photoelectric conversion elements are formed. Between adjacent photoelectric conversion elements, the collector grid 3 that is covered by the protective layer 4 and serves as an interconnect for current collection is formed. One photoelectric conversion element is formed with the porous photoelectric conversion layer 5, the electrolyte layer 6, and the catalyst layer 7a stacked between the window electrode (working electrode) and the counter electrode.

In the opposed cell, each of the photoelectric conversion elements separated by the collector grid 3 covered by the protective layer 4 is formed between the transparent electrically-conductive film 2 of the window electrode (working electrode) and the opposing electrode 8 of the counter electrode, and each photoelectric conversion element is electrically connected to two adjacent collector grids 3.

That is, the opposed cell is formed of plural photoelectric conversion elements and is composed of the window electrode (working electrode) on which light is incident, the counter electrode disposed opposed to it, and the electrolyte layer 6 disposed between the window electrode (working electrode) and the counter electrode. The window electrode (working electrode) is composed of the transparent substrate 1, the transparent electrically-conductive film 2, the collector grid 3, the protective layer 4, and the porous photoelectric conversion layer 5 formed of a porous oxide semiconductor layer carrying a dye. The counter electrode is composed of the catalyst layer 7a, the opposing electrode 8, the opposing substrate 9, and the sealant layer 10.

If the opposing substrate 9 is formed of a metal such as titanium or SUS, the provision of the opposing electrode 8 may be omitted. The electrolyte layer 6 disposed between the window electrode (working electrode) and the counter electrode is sealed by the sealant layer 10.

Each of the porous photoelectric conversion layer 5 and the catalyst layer 7a is formed in a strip manner on plural columns. In the example shown in FIG. 6A and FIG. 6B, the catalyst layer 7a is discontinuously formed. At the discontinuous part between the adjacent strip catalyst layers 7a, the opposing electrode 8 is in contact with the electrolyte layer 6 and the tip of the protective layer 4 is opposed to the opposing electrode 8. Such a structure can increase the thickness of the collector grid 3 and enhance the current collection efficiency.

It is also possible to employ a structure in which the catalyst layer 7a is continuously formed and a concave part (trench) is formed in the catalyst layer 7a corresponding to the position at which the tip of the protective layer 4 is opposed to the opposing electrode 8. In such a structure, the catalyst layer 7a continuously formed is in contact with the electrolyte layer 6 across its whole surface area. Thus, reduction reaction of oxidized redox ions is promoted and the conversion efficiency can be enhanced. Furthermore, similarly to the above description, the thickness of the collector grid 3 can be increased and the current collection efficiency can be enhanced.

The following advantage is also achieved by discontinuously forming the catalyst layer 7a or by continuously forming the catalyst layer 7a and providing the concave part (trench). Specifically, if an electrolyte liquid is used as the electrolyte layer 6, the electrolyte liquid poured from the opening part (not shown) rapidly diffuses into the discontinuous part of the catalyst layer 7a or the concave part (trench). Thus, the electrolyte liquid is efficiently injected into the narrow gaps between the porous photoelectric conversion layer 5 and the catalyst layer 7a.

Each of the collector grid 3 and the protective layer 4 has a narrow width and is formed in a line manner on plural columns. In the dye-sensitized solar cell having a large light reception area, the interconnect for current collection like the collector grid 3 is indispensable. Increase in the gap between the window electrode (working electrode) and the counter electrode due to forming of the interconnect for current collection causes the lowering of the conversion efficiency. Thus, this gap needs to be set as short as possible.

The transparent substrate 1 may be any substrate as long as it is transparent in the visible region. A glass substrate, a ceramic substrate, a resin substrate, or a film can be used as the transparent substrate 1. For example, soda glass, heat-resistance glass, and quartz glass can be used as glass, and alumina and the like can be used as ceramics. As a resin, e.g. polyethylene terephthalate (PET), polyethylene naphthalate (PEN), polycarbonate (PC), and polyether sulfone (PES) can be used.

As the transparent electrically-conductive film 2, e.g. the following electrically-conductive metal oxides can be used: indium oxide, indium oxide doped with tin (ITO), indium oxide doped with zinc (IZO), tin oxide, tin oxide doped with antimony (ATO), tin oxide doped with fluorine (FTC)), zinc oxide, and zinc oxide doped with aluminum (AZO).

The collector grid (interconnect layer for current collection) 3 is formed from a material having resistance lower than that of the transparent electrically-conductive film 2. For example, Au, Ag, Al, Cu, Ti, Ni, Fe, Zn, Mo, W, Cr, or a compound or an alloy of these metals can be used, and the collector grid 3 may be formed in a grid manner, a stripe manner, or a comb manner.

The protective layer 4 may be any layer as long as it is formed of a material having corrosion resistance against an electrolytic liquid such as an iodine electrolytic liquid. The protective layer 4 shields the electrically-conductive interconnect layer from the electrolyte and prevents reverse electron transfer reaction and the corrosion of the electrically-conductive interconnect. As the protective layer 4, the following materials can be used: metal oxides; metal nitrides such as TiN and WN; glass such as low-melting-point glass frit; and resins such as epoxy, silicone, polyimide, acrylic, polyisobutylene, ionomer, and polyolefin.

As the material of the porous oxide semiconductor layer, one generally used as a photoelectric conversion material can be used. For example, the following semiconductor compounds can be used: titanium oxide (TiO₂), zinc oxide (ZnO), tungsten oxide (WO₃), niobium oxide (Nb₂O₅), strontium titanate (SrTiO₃), tin oxide (SnO₂), indium oxide (In₃O₃), zirconium oxide (ZrO₂), thallium oxide (Ta₂O₅), lanthanum oxide (La₂O₃), yttrium oxide (Y₂O₃), holmium oxide (Ho₂O₃), bismuth oxide (Bi₂O), cerium oxide (CeO₂), and alumina (Al₂O₃).

As the dye that is adsorbed to the porous oxide semiconductor layer and functions as a photosensitizer, known various compounds having absorption in the visible light region and/or the infrared region can be used. Organic dyes, metal complex dyes, etc. can be used. Examples of the usable organic dyes include azo-based dye, quinone-based dye, quinoneimine-based dye, quinacridone-based dye, squarylium-based dye, cyanine-based dye, merocyanine-based dye, triphenylmethane-based dye, xanthene-based dye, porphyrin-based dye, phthalocyanine-based dye, perylene-based dye, indigo-based dye, and naphthalocyanine-based dye. Examples of the usable metal complex dyes include ruthenium-based metal complex dyes such as ruthenium bipyridine-based metal complex dye, ruthenium terpyridine-based metal complex dye, and ruthenium quaterpyridine-based metal complex dye. To tightly adsorb the dye to the porous oxide semiconductor layer, it is preferable to use a dye having, in its dye molecule, an interlocking group such as carboxyl group, alkoxy group, hydroxyl group, hydroxyalkyl group, sulfonic acid group, ester group, mercapto group, and phosphonyl group. A dye having the carboxyl group (COOH group) among them is particularly preferable. In general, the interlocking group has a function to adsorb and fix a dye to a semiconductor surface and supplies electrical coupling that facilitates electron transfer between the dye in the excited state and the conduction band of the porous oxide semiconductor layer.

As the opposing substrate 9 used for the counter electrode, a glass plate, a resin sheet, or a film on which a transparent electrically-conductive film of e.g. ITO or FTO is formed, or a glass plate, a plastic sheet, or a film on which a metal film of e.g. Pt, Ir, or Ru is formed can be used. In this case, the transparent electrically-conductive film and the metal film serve as the opposing electrode 8. If a metal substrate or foil is used as the opposing substrate 9, the provision of the opposing electrode 8 may be omitted.

The catalyst layer 7a may be any layer as long as it has such catalytic ability as to promote reduction reaction of oxidized redox ions such as I₃⁻ ions in the electrolytic liquid and allow the reduction reaction at sufficiently high speed. For example, a layer formed of Pt, carbon (C), Rh, Ru, or Ir can be used.

As the electrolyte used for forming the electrolyte layer 6, various electrolyte solutions containing cations such as lithium ions and anions such as iodine ions can be used. It is preferable that a redox pair capable of reversibly taking the oxidized form and the reduced form exist in this electrolyte. Examples of such a redox pair include iodine-iodine compound, bromine-bromine compound, and quinone-hydroquinone. Besides the liquid electrolyte, a gel electrolyte, a solid electrolyte, and a molten salt gel electrolyte can be used.

The sealant layer 10 bonds the counter electrode to the window electrode (working electrode). Furthermore, it prevents leakage and volatilization of the electrolyte layer 6 and prevents impurities from the external from entering the internal. As the sealant layer 10, a resin having resistance against the electrolyte used for forming the electrolyte layer 6 is used. For example, a heat sealing film, a heat-curable resin, and an ultraviolet-curable resin can be used.

As shown in FIG. 6B, H, Hₜ, H_{c}, Hₚ, Hₐ, g, W_{c}, Wₚ, and Wₐ are defined as follows. H denotes the interval between the opposed surfaces of the transparent electrically-conductive layer 2 and the opposing electrode 8. Hₜ denotes the thickness of the porous photoelectric conversion layer 5. H_{c} denotes the thickness of the catalyst layer 7a. Hₚ denotes the distance from the surface of the transparent electrically-conductive layer 2 to the tip of the protective layer 4. Hₐ denotes the distance from the surface of the transparent electrically-conductive layer 2 to the tip of the collector grid 3. g denotes the interval between the opposed surfaces of the porous photoelectric conversion layer 5 and the catalyst layer 7a. W_{c} denotes the interval between the adjacent catalyst layers 7a formed in a strip manner. Wₚ denotes the external width of the protective layer. Wₐ denotes the external width of the collector grid 3.

The thickness Hₜ of the porous photoelectric conversion layer 5 formed by making an oxide semiconductor layer carry a dye is the distance between the average surfaces obtained by averaging concave and convex of the respective surfaces of the transparent electrically-conductive layer 2 and the porous photoelectric conversion layer 5. The thickness H_{c} of the catalyst layer 7a is the distance between the average surfaces obtained by averaging concave and convex of the respective surfaces of the opposing electrode 8 and the catalyst layer 7a. The interval g between the porous photoelectric conversion layer 5 and the catalyst layer 7a is the distance between the average surfaces obtained by averaging concave and convex of the respective surfaces of the porous photoelectric conversion layer 5 and the catalyst layer. The sum of the thickness Hₐ of the collector grid 3 and the thickness of the protective layer 4 is Hₚ.

As shown in FIG. 6B, H>(Hₜ+H_{c}), i.e. g>0, is satisfied. That is, the porous photoelectric conversion layer 5 and the catalyst layer 7a are separately disposed so as not to get contact with each other. Furthermore, H>Hₚ>(Hₜ+g) is satisfied. That is, the tip of the protective layer 4 is so located as not to get contact with the surface of the opposing electrode 8 opposed to this tip, between the adjacent strip catalyst layers 7a discontinuously formed in a strip manner on plural columns. In addition, W_{c}>Wₚ>Wₐ is satisfied. That is, the protective layer 4 is so formed as not to get contact with the catalyst layer 7a.

By employing such a configuration, the current collection efficiency can be enhanced by increasing the thickness of the collector grid 3 and the collector grid 3 can be surely protected by the protective layer 4. Furthermore, the porous photoelectric conversion layer 5 and the catalyst layer 7a can be disposed close to each other and the lowering of the conversion efficiency occurring due to resistive loss by the electrolyte layer 6 can be suppressed. Moreover, the lowering of the conversion efficiency due to the contact of the porous photoelectric conversion layer 5 with the catalyst layer 7a or the opposing electrode 8 can be suppressed.

In the comparative example shown in FIG. 6C, the positional relationship between the catalyst layer 7b obtained by monolithically forming the catalyst layer 7a shown in FIG. 6A and FIG. 6B and the opposing electrode 8 is shown. If the thickness of the catalyst layer 7b and the thickness of the porous photoelectric conversion layer 5 are defined as Hₚ and Hₜ, respectively, and the distance from the surface of the transparent electrically-conductive layer 2 to the tip of the protective layer 4 is defined as Hₚ similarly to the case shown in FIG. 6A and FIG. 6B, the interval between the porous photoelectric conversion layer 5 and the catalyst layer 7b is (Hₚ−Hₜ). Apparently this interval is longer than g in FIG. 6A and FIG. 6B, and thus the lowering of the conversion efficiency occurring due to resistive loss by the electrolyte layer 6 is larger. Furthermore, because Hᵣ>H is satisfied, the structure shown in the comparative example has a larger thickness.

As just described, it is apparent that the opposed cell shown in FIG. 6A and FIG. 6B has a smaller thickness and the lowering of the conversion efficiency occurring due to resistive loss by the electrolyte layer 6 is suppressed compared with the comparative example shown in FIG. 6C.

The thickness of each layer configuring the opposed cell is as follows for example.

The thickness of the transparent substrate 1 has no limit and can be freely selected in matching with the configuration of the opposed cell. However, in terms of the mechanical strength and the weight, the thickness is normally from 0.5 mm to 10 mm, and preferably from 1 mm to 5 mm.

The thickness of the transparent electrically-conductive film 2 has no limit and can be freely selected in matching with the configuration of the opposed cell. However, in terms of the balance between the light transmittance and the sheet resistance, the thickness is from 50 nm to 2000 nm, and preferably from 100 nm to 1000 nm.

The thickness of the collector grid 3 is designed depending on the size of the opposed cell and the magnitude of the current flowing therein. Although a larger thickness can provide lower resistance, proper values of the thickness exist because the larger thickness leads to larger thickness of the sealing layer and larger thickness of the catalyst layer. Specifically, the thickness is normally from 0.1 μm to 100 μm, and preferably from 1 μm to 50 μm.

The thickness of the protective layer 4 has no limit as long as the collector grid can be completely shielded from the electrolyte. However, the thickness is normally from 0.1 μm to 100 μm, and preferably from 1 μm to 50 μm.

The optimum value of the thickness of the porous photoelectric conversion layer 5 differs depending on the dye used. The thickness is normally from 1 μm to 100 μm, and preferably from 5 μm to 50 μm.

The thickness of the electrolyte layer 6 is represented by g shown in FIG. 6B. A smaller thickness of the electrolyte layer provides lower resistance of ion diffusion and thus is more preferable. However, too small a thickness causes short-circuiting between the porous semiconductor electrode and the catalyst layer. Therefore, the thickness is preferable from 0.1 μm to 100 μm, and more preferably from 1 μm to 50 μm.

A larger thickness of the catalyst layer 7a is more preferable also in the sense of increasing the surface area. However, the larger thickness leads to a larger thickness of the sealing layer. The thickness is normally from 1 μm to 200 μm, and preferably from 5 μm to 100 μm.

The thickness of the opposing electrode 8 has no limit and can be freely selected in matching with the configuration of the opposed cell. However, the thickness is normally from 0.1 μm to 10 μm, and preferably from 1 μm to 5 μm.

The thickness of the sealing layer 10 has no limit and can be freely selected in matching with the configuration of the opposed cell. However, too large a thickness of the sealing layer possibly causes poor sealing performance. The thickness is normally from 1 μm to 200 μm, and preferably from 10 μm to 100 μm.

### <Electron Flow Direction in Opposed Cell>

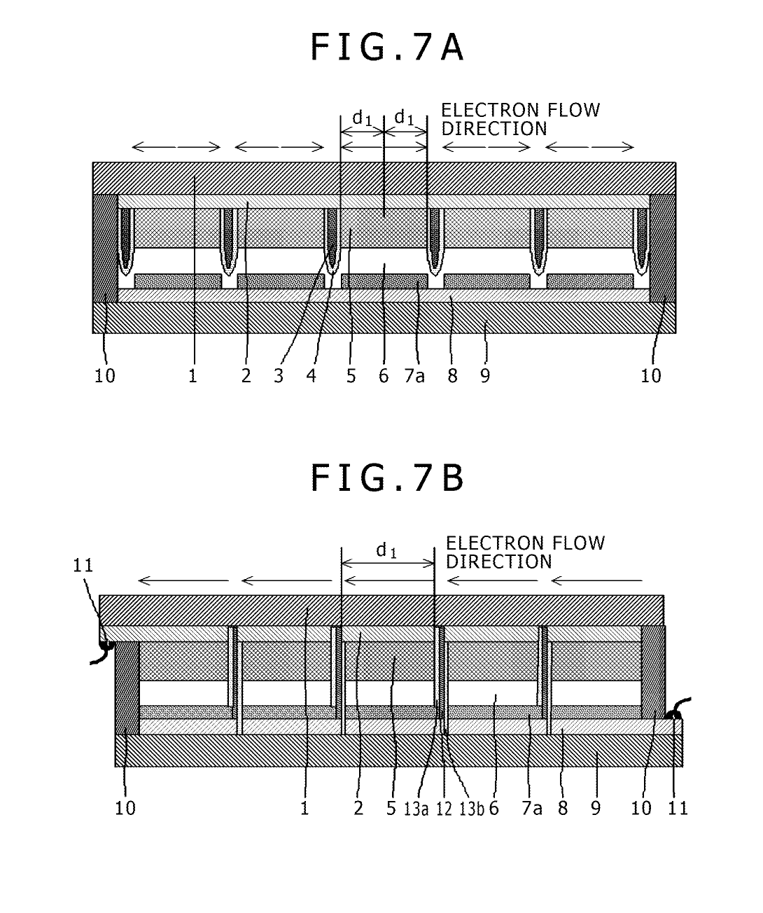

FIGS. 7A and 7B are sectional views for explaining the electron flow direction in the dye-sensitized solar cell (opposed cell) in the embodiment of the present invention.

FIG. 7A is a diagram for explaining the electron movement direction in the opposed cell, and FIG. 7B is a diagram for explaining the electron movement direction in a Z-module as a comparative example.

As shown in FIG. 7B, in the Z-module, the electrolyte layer 6 is disposed between the transparent substrate 1 over which the transparent electrically-conductive film 2 and the porous photoelectric conversion layer 5 are sequentially pattern-formed into a strip shape and the opposing substrate 9 over which the opposing electrode 8 and the catalyst layer 7a are sequentially pattern-formed into a strip shape, and plural photoelectric conversion elements are formed. Between adjacent photoelectric conversion elements, an electrically-conductive connecting layer 12 sandwiched by a pair of insulating barrier layers 13a and 13b is formed. This electrically-conductive connecting layer 12 electrically connects the transparent electrically-conductive film 2 to the opposing electrode 8. The insulating barrier layers 13a and 13b serve as the barrier between photoelectric conversion elements and as protective layers for the electrically-conductive connecting layer 12. The photoelectric conversion element is configured by stacking of the porous photoelectric conversion layer 5, the electrolyte layer 6, and the catalyst layer 7a.

In the Z-module, each of the photoelectric conversion elements separated by the pair of insulating barrier layers 13a and 13b is formed between the transparent electrically-conductive film 2 of the window electrode (working electrode) and the opposing electrode 8 of the counter electrode. Furthermore, the transparent electrically-conductive film 2 and the opposing electrode 8 of adjacent photoelectric conversion elements are coupled to each other by using the electrically-conductive connecting layer 12 so as to be electrically connected to each other (series connection). In the Z-module, the electron flow direction is one direction.

As shown in FIG. 7A, in the opposed cell, electrons moving in the transparent electrically-conductive film 2 flow into the collector grid 3 formed at the closest position. Therefore, the maximum movement distance of the electrons is equal to or shorter than (d₁+(thickness of protective layer)). This distance is almost half the distance between the adjacent collector grids 3.

On the other hand, in the Z-module shown in FIG. 7B, the maximum movement distance of electrons is equal to the distance between the adjacent electrically-conductive connecting layers 12.

As is apparent from comparison between FIG. 7A and FIG. 7B, when consideration is made about the Z-module and the opposed cell in which the porous photoelectric conversion layer 5 of one photoelectric conversion element has the same width, the electron movement distance in the opposed cell is almost half that in the Z-module. When consideration is made about the Z-module and the opposed cell in which resistive loss by the transparent electrically-conductive film 2 is equal to or smaller than the same certain value, if the distance between the adjacent electrically-conductive connecting layers 12 in the Z-module is defined as d₁, resistive loss by the transparent electrically-conductive film 2 in the opposed cell is equivalent to that in the Z-module when the distance between the adjacent collector grids 3 is 2d₁ in the opposed cell.

A working example relating to the opposed cell will be described next.

### Working Example

### Example of Layer Configuration of Opposed Cell

Specific examples of the respective layers configuring the opposed cell shown in FIG. 1 to FIG. 3B will be described below.

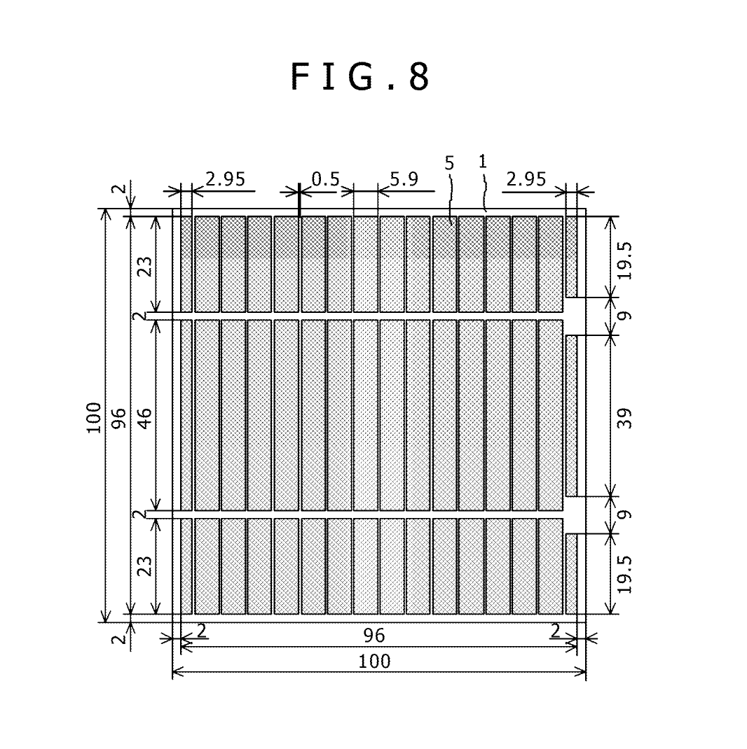

FIG. 8 is a diagram for explaining the pattern of the porous photoelectric conversion layer (porous oxide semiconductor layer, TiO₂ electrode) 5 in a working example of the present invention.

As shown in FIG. 8, the pattern of the porous photoelectric conversion layer 5 is formed with a thickness of 20 μm on a surface of the transparent substrate (transparent glass substrate (FTO glass substrate on which FTO is formed)) 1. The pattern is composed of sixteen columns and three rows of the porous photoelectric conversion layer 5 having a pattern of strips of 2.95 mm×23 mm, 2.95 mm×46 mm, 2.95 mm×19.5 mm, 2.95 mm×39 mm, 5.9 mm×23 mm, and 5.9 mm×46 mm.

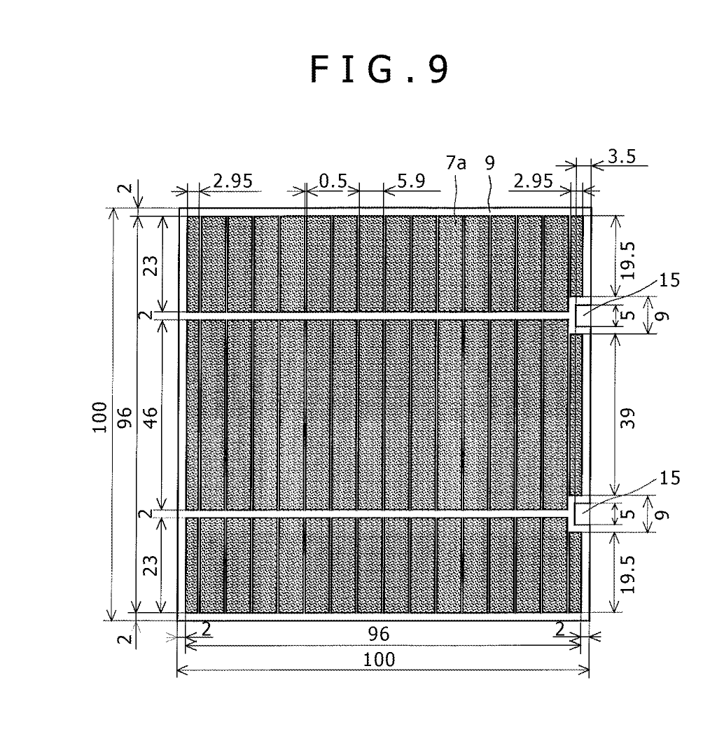

FIG. 9 is a diagram for explaining the pattern of the catalyst layer (carbon electrode) in the working example of the present invention.

As shown in FIG. 9, the pattern of the catalyst layer 7a has the same shape as that of the pattern of the porous photoelectric conversion layer 5 and is formed of a metal (titanium (Ti)) with a thickness of 50 μm. The pattern is formed on a surface of the opposing substrate 9 in which the concave notch parts 15 are formed at one side.

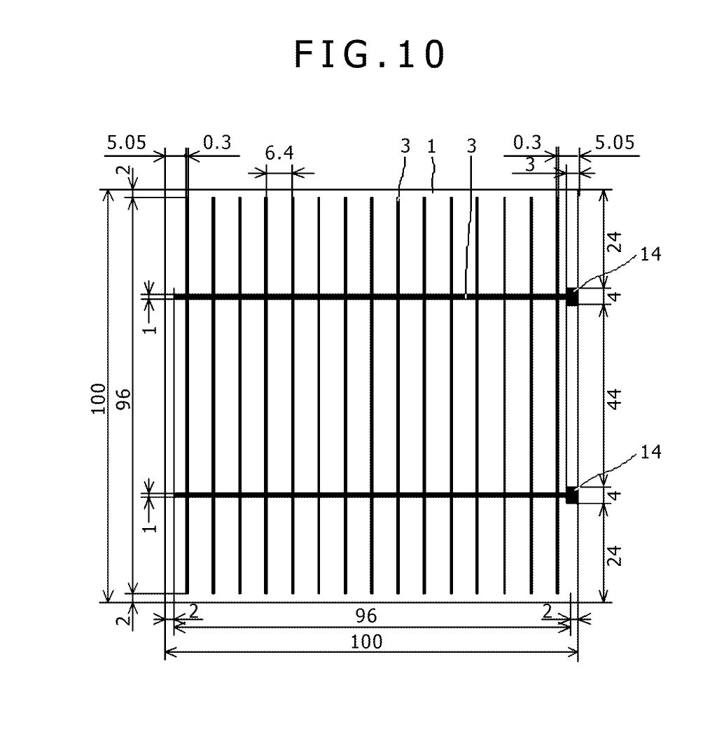

FIG. 10 is a diagram for explaining the pattern of the collector grid (e.g. Ag electrode) in the working example of the present invention.

As shown in FIG. 10, the pattern of the collector grid 3 includes repetition of line patterns each having a width of 0.3 mm, a length of 96 mm, and a thickness of 30 μm on fifteen columns, and is formed on a surface of the transparent substrate 1. The collector grids 3 on fifteen columns are connected to each other by two line patterns each having a width of 1 mm, a length of 95 mm, and a thickness of 30 μm, and are connected to the connection terminals 14 having a rectangular pattern with a thickness of 30 μm and a size of 3 mm×4 mm.

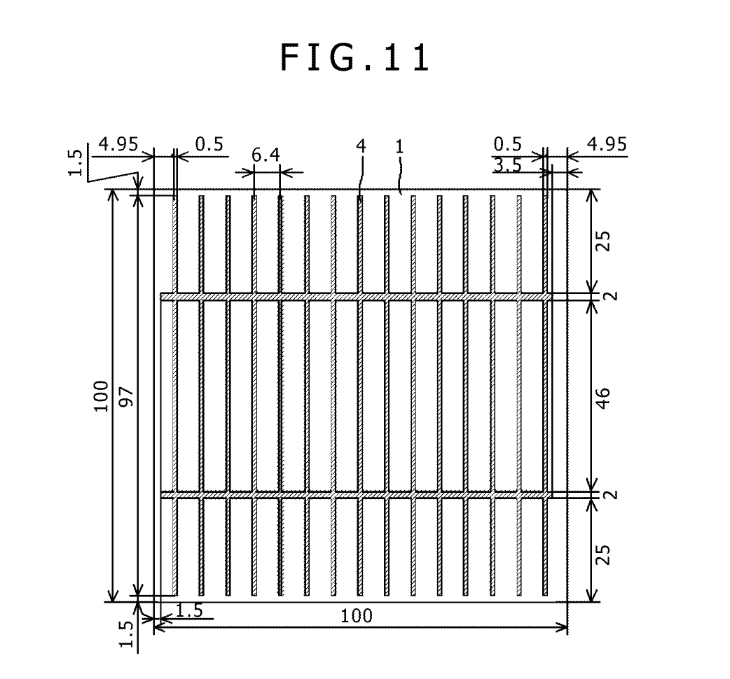

FIG. 11 is a diagram for explaining the pattern of the protective layer (Ag-electrode protecting layer) in the working example of the present invention.

As shown in FIG. 11, the protective layer 4 is formed of an epoxy-based resin and its pattern includes repetition of line patterns each having a width of 0.5 mm, a length of 97 mm, and a thickness of 20 μm on fifteen columns. The protective layers 4 on fifteen columns are connected to each other by two line patterns each having a width of 2 mm, a length of 95 mm, and a thickness of 20 μm, and are formed on a surface of the transparent substrate 1 in such a manner as to cover the respective columns and rows of the pattern of the collector grid 3.

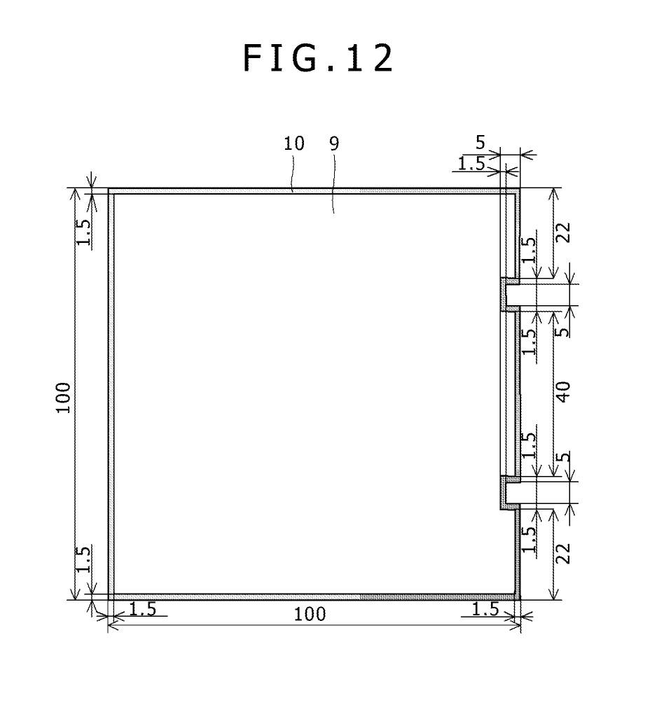

FIG. 12 is a diagram for explaining the pattern of the sealant layer in the working example of the present invention.

As shown in FIG. 12, the sealant layer 10 is formed of a UV-curable resin and the width of its pattern is 1.5 mm. The sealant layer 10 is continuously formed along the outer periphery of the opposing substrate 9, in which the concave notch part 15 is formed at two places of one side.

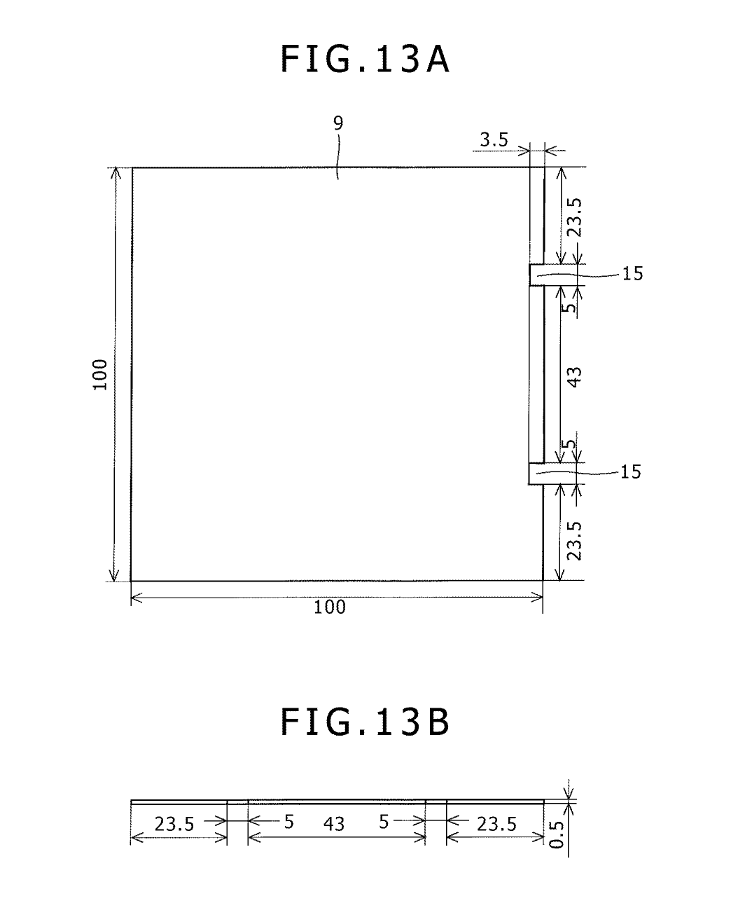

FIGS. 13A and 13B are diagrams for explaining the shape of the opposing substrate in the working example of the present invention.

As shown in FIGS. 13A and 13B, the opposing substrate 9 is a 0.5-mm-thickness metal plate (e.g. titanium plate) in which the concave notch part 15 is formed at two places of one side. The whole opposing substrate 9 works as an electrode. Furthermore, because the opposing substrate 9 is a metal, an injection opening through which an electrolyte liquid for forming the electrolyte layer 6 is injected can be formed in this opposing substrate 9 and the injection opening can be sealed by laser welding after injection of the electrolyte liquid. Thus, the sealing performance of the end seal is dramatically enhanced.

A description will be made below about the optimum width (electrode width) of the porous oxide semiconductor layer (TiO₂) of the photoelectric conversion element in the opposed cell.

### <Calculation Model of Optimum Electrode Width and Calculation Result Example>

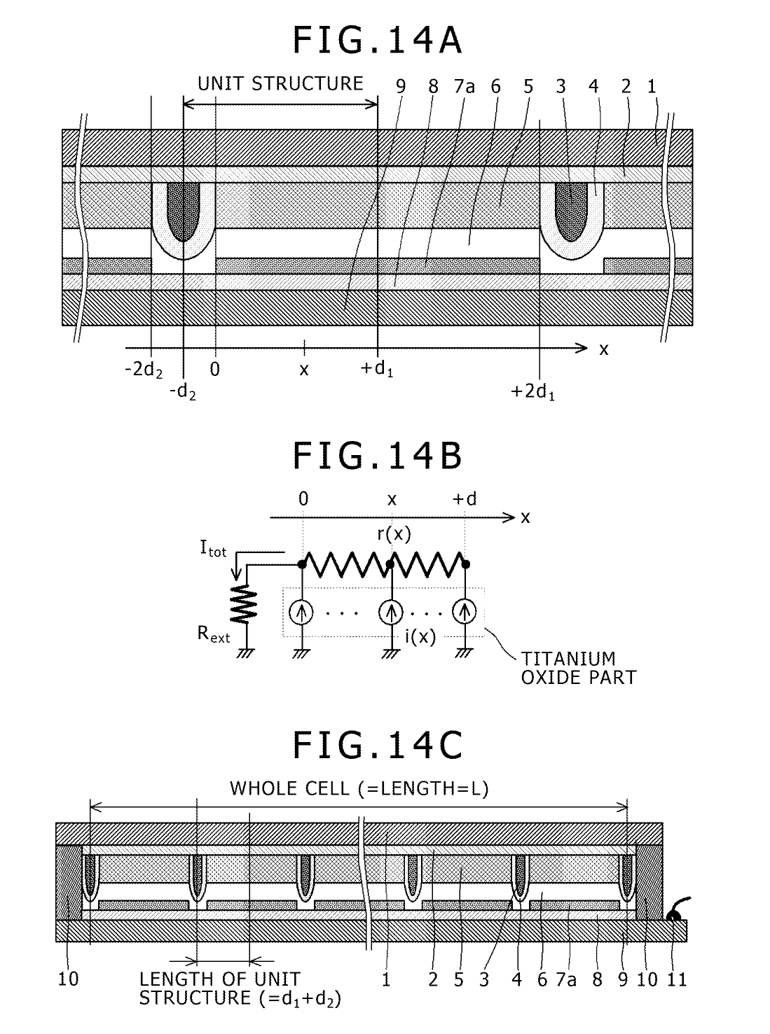

FIGS. 14A to 14C are sectional views for explaining the relationship between the opposed cell in the working example of the present invention and its unit structure and derivation of the optimum electrode width.

FIG. 14A is a diagram for explaining the unit structure in the opposed cell. FIG. 14B is a diagram for explaining a circuit that simulates area [0, d₁] in this unit structure. FIG. 14C is a diagram for explaining expansion of the unit structure to the whole opposed cell.

As shown in FIG. 14A, the unit structure in the opposed cell is defined as a structural body in the area between the center position of one collector grid 3 and the intermediate point at the equal distance from the adjacent collector grid 3. Specifically, as shown in FIG. 14A, when the x axis is set, this unit structure is a structural body represented by an area having a length of (d₁+d₂), defined by the area of half of the collector grid 3 and the protective layer 4 (−d₂≦x≦0) and the adjacent area linked to this area (0≦x≦d₁). This d₁ corresponds to the intermediate point at the equal distance from the adjacent collector grid 3 and 2d₂ is defined as the total width of the protective layer 4. When one photoelectric conversion element is defined as the area between the respective center positions of the adjacent collector grids 3, this structural body (unit structure) is defined as (½) of the photoelectric conversion element.

Analysis will be performed with replacement of the unit structure in the opposed cell by the simulating circuit shown in FIG. 14B, obtained by simplifying each of the transparent electrically-conductive film 2 and the porous photoelectric conversion layer 5 to a one-dimensional entity and reversing the current direction. For this analysis, the current element (A/m) at position x (0≦x≦d₁) of the porous oxide semiconductor layer (TiO₂) serving as the porous photoelectric conversion layer 5 is defined as i(x). The line resistivity (Ω/cm) at position x (0≦x≦d₁) of the FTO film serving as the transparent electrically-conductive film 2 is defined as r(x). The total current flowing from the FTO film to an external load Rₑₓₜ is defined as Iₜₒₜ.

As shown in FIG. 14C, the whole opposed cell can be represented by repetition of the above-described structural body (unit structure). Therefore, for example, when the length of the whole cell is L as shown in FIG. 14C, the number n of structural bodies (unit structures) included in the length L of this whole cell is n=L/(d₁+d₂). The power output of the whole cell is equal to n times the cell power output of the structural body (unit structure).

The intensity of light incident on the transparent electrically-conductive film 2 at position x is defined as I(x), and the cell power output of the structural body (unit structure) on which light having a constant value as I(x) and thus having uniform intensity distribution is incident, i.e. how far the width of the porous photoelectric conversion layer 5 of one photoelectric conversion element can be enlarged, is calculated (simulation) in the following manner. Thereby, the optimum width of the porous photoelectric conversion layer 5 can be obtained.

Voltage V(x) at position x of the transparent electrically-conductive film 2 is given by Equation (1). Joule heat Pₗₒₛₛ(x) attributed to current element i(x) at position x is given by Equation (2). Joule heat P_{unit loss} generated in the whole transparent electrically-conductive film 2 is given by Equation (3).

$$\begin{matrix}V ( x ) = {R}_{ext} {I}_{tot} + {\int }_{0}^{x} r ( x ) d x \cdot {\int }_{x}^{{d}_{1}} i ( x ) d x & ( 1 ) \\ \begin{matrix}{P}_{loss} ( x ) = [ V ( x ) - V ( 0 ) ] \cdot i ( x ) \\ = [ {\int }_{0}^{x} r ( x ) d x \cdot {\int }_{x}^{{d}_{1}} i ( x ) d ( x ) ] i ( x ) \end{matrix} & ( 2 ) \\ \begin{matrix}{P}_{unit loss} = {\int }_{0}^{{d}_{1}} {P}_{loss} ( x ) d x \\ = {\int }_{0}^{{d}_{1}} [ {\int }_{0}^{x} r ( x ) d x \cdot {\int }_{x}^{{d}_{1}} i ( x ) d x ] i ( x ) d x\end{matrix} & ( 3 )\end{matrix}$$

If the generated power at position x of the porous oxide semiconductor layer (TiO₂) is defined as P_{gen}(x), the generated power P_{unit gen} arising from the whole porous oxide semiconductor layer (TiO₂) included in the above-described structural body (unit structure) is given by Equation (4).

$${P}_{unit gen} = {\int }_{0}^{{d}_{1}} {P}_{gen} ( x ) d x \qquad ( 4 )$$

As described above, the number n of structural bodies (unit structures) included in the whole opposed cell having the length L is n=L/(d₁+d₂). Therefore, when L is defined as the unit length=1, the available generated power P_{cell} by the whole opposed cell is given by Equation (5).

$$\begin{matrix}{P}_{cell} = n \cdot ( {P}_{unit gen} ( x ) - {P}_{unit loss} ( x ) ) \\ = ( 1 / {d}_{1} + {d}_{2} ) ) \{ {\int }_{0}^{{d}_{1}} {P}_{gen} ( x ) d x - \\ {\int }_{0}^{{d}_{1}} [ {\int }_{0}^{x} r ( x ) d x \cdot {\int }_{x}^{{d}_{1}} i ( x ) d x ] i ( x ) d x \}\end{matrix} \qquad ( 5 )$$

Therefore, through calculation of ∂P_{cell}/∂d₁=0, d₁ that provides the maximum available generated power P_{cell} is obtained.

Based on the assumption that light having uniform intensity distribution is incident on the structural body (unit structure), r(x)=r (Ω/cm) and i(x)=i (A/m) are substituted in Equation (5). In addition, ∫P_{gen}(x)dx=d₁×P_{gen*} is substituted in the first term in the curly bracket { } in Equation (5) and the integral is performed. As a result, Equation (6) can be obtained.

P_{cell}=(d₁/d₁+d₂))[P_{gen*}−(r(id₁)²/6)] (6)

In Equation (6), d₁/(d₁+d₂) denotes the term of the aperture ratio (representing the ratio of the area contributing to power generation) of the photoelectric conversion element. P_{gen*} denotes the term of power generation. r(id₁)²/6 denotes the term of loss.

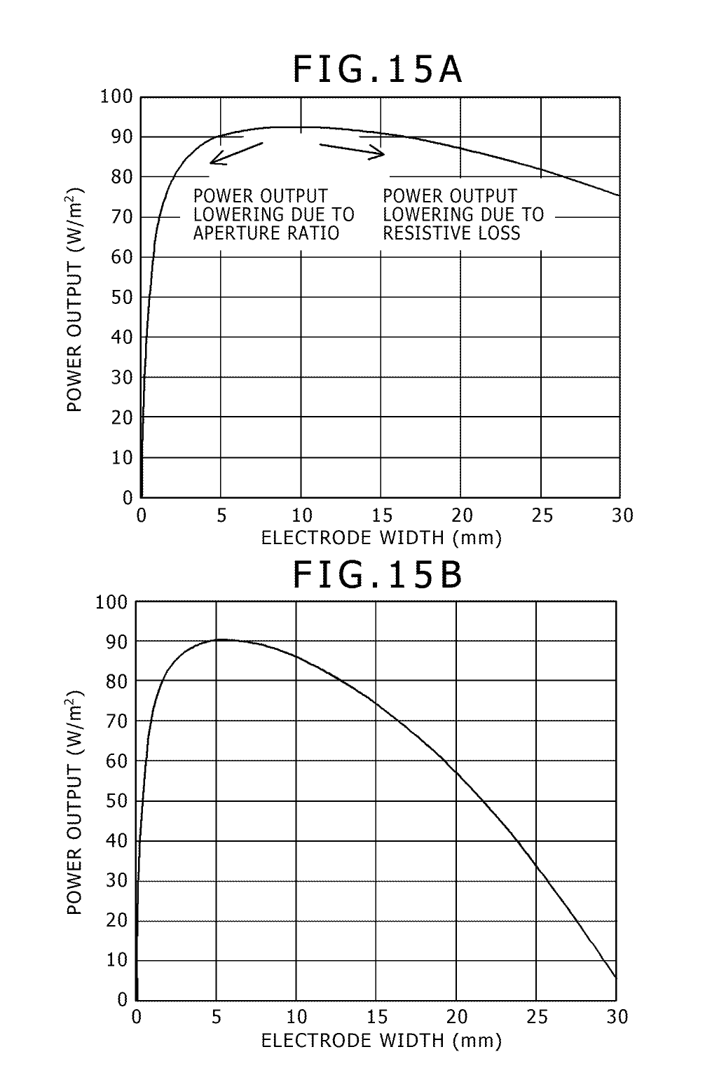

FIGS. 15A and 15B are diagrams for explaining the optimum electrode width in the working example of the present invention. FIG. 15A is a diagram for explaining the optimum electrode width in the opposed cell. FIG. 15B is a diagram for explaining the optimum electrode width in a Z-module. In FIGS. 15A and 15B, the abscissa indicates the width of the porous oxide semiconductor layer (TiO₂) (electrode width) (mm), and the ordinate indicates the power output (W/m²).

The width of the porous oxide semiconductor layer (TiO₂) is defined as D (electrode width) and the line resistivity (Ω/cm) of the FTO film serving as the transparent electrically-conductive film 2 is set to r(x)=10 (Ω/□). In addition, d₂=0.25 (mm), i (average generated current (experimental value))=250 (A/m²), and P_{gen*}=100 (W/m²) are set. In this case, because d₁=(D/2) is satisfied, the power output (W/m²) is given by P_{cell}=(D/(D+0.5)){100−0.02604D²} from equation (6). FIG. 15A shows the dependence of the power output (W/m²) obtained by using this equation on the electrode width (D).

The curve shown in FIG. 15A has the maximum value when D=9.60 (mm). In the region of D<9.6, the curve shows power output lowering due to the decrease in the aperture ratio. In the region of D>9.6, the curve shows power output lowering due to the resistance of the FTO film serving as the transparent electrically-conductive film 2.

For the Z-module, in Equation (6), the width of the porous oxide semiconductor layer (TiO₂) is defined as D (electrode width) and the line resistivity (Ω/cm) of the FTO film serving as the transparent electrically-conductive film 2 is set to r(x)=10 (Ω/□). In addition, d₂=0.4 (mm), i (average generated current (experimental value))=250 (A/m²), and P_{gen*}*=100 (W/m²) are set. In this case, because d₁=D is satisfied, the power output (W/m²) is given by P_{cell}=(D/(D+0.4)){100−0.10417 D²}. FIG. 15B shows the dependence of the power output (W/m²) obtained by using this equation on the electrode width (D).

The curve shown in FIG. 15B has the maximum value when D≈5.6 (mm). In the region of D<5.6, the curve shows power output lowering due to the decrease in the aperture ratio. In the region of D>5.6, the curve shows power output lowering due to the resistance of the FTO film serving as the transparent electrically-conductive film 2.

In the above-described manner, by using the average generated current (experimental value), the optimum value of the electrode width (D) could be obtained for the opposed cell and the Z-module. As is apparent from comparison between the curve shown in FIG. 15A and the curve shown in FIG. 15B, the power output lowering due to the increase in the electrode width (D) shows a gentle change in FIG. 15A but shows a rapid change in FIG. 15B. That is, it is apparent that the opposed cell yields a higher power output when comparison is made between the opposed cell and the Z-module having the same electrode width (D).

An opposed cell according to the embodiment of the present invention can be obtained by bonding the transparent substrate (transparent glass substrate (e.g. FTO glass substrate on which FTO is formed)) 1 having an outer shape of 100 mm×100 mm on which the patterns of the porous photoelectric conversion layer 5, the collector grid 3 serving as an interconnect for current collection, and the protective layer 4 are formed and the opposing substrate 9 formed of a metal (e.g. titanium plate) having an outer shape of 100 mm×100 mm on which the patterns of the catalyst layer 7a and the sealant layer 10 are formed to each other by the sealant layer 10 without misalignment. Therefore, the outer shape of the opposed cell is also 100 mm×100 mm. Thus, tiling (arranging) of plural opposed cells can be easily carried out and a large-size solar cell module can be provided.

Although the embodiment of the present invention has been described above, the present invention is not limited to the above-described embodiment and various kinds of modifications can be made based on the technical idea of the present invention.

The present invention can provide a dye-sensitized solar cell that has a simple structure and allows enhancement in the conversion efficiency and easy mutual connection, and a solar cell module obtained by disposing the dye-sensitized solar cells in a plane and connecting them to each other.

The present application contains subject matter related to that disclosed in Japanese Priority Patent Application JP 2010-080220 filed in the Japan Patent Office on Mar. 31, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion device comprising:
a first substrate;
a collector layer configured to be provided over the first substrate;
a second substrate configured to be opposed to a planar surface of the first substrate and be formed of a metal having a concave notch part at one side; and
a connection terminal configured to be connected to the collector layer, wherein
the connection terminal is disposed opposed to the concave notch part.

2. The photoelectric conversion device according to claim 1, further comprising:
a transparent electrically-conductive layer configured to be formed on the first substrate;
an oxide semiconductor layer configured to be formed on a surface of the transparent electrically-conductive layer in a strip manner on a plurality of columns and carry a dye;
a protective layer configured to cover a surface of the collector layer;
a catalyst layer configured to be formed over the second substrate; and
an electrolyte layer configured to be formed between the first substrate and the second substrate, wherein
the second substrate has a continuous flat surface opposed to the planar surface of the first substrate,
the collector layer is formed on the surface of the transparent electrically-conductive layer in a line manner on a plurality of columns in such a manner as to sandwich the oxide semiconductor layer,
the catalyst layer is continuously or discontinuously formed over the flat surface,
the oxide semiconductor layer and the catalyst layer are disposed opposed to each other, and
a tip of the protective layer is disposed at a position between a surface of the catalyst layer and the flat surface.

3. The photoelectric conversion device according to claim 2, wherein
H>(Hₜ+H_{c}) and H>Hₚ>(Hₜ+g) are satisfied when H is distance between the surface of the transparent electrically-conductive layer and the flat surface, Hₜ is thickness of the oxide semiconductor layer, H_{c} is thickness of the catalyst layer, Hₚ is distance between the surface of the transparent electrically-conductive layer and the tip of the protective layer, and g is an interval between opposed surfaces of the oxide semiconductor layer and the catalyst layer.

4. The photoelectric conversion device according to claim 2, wherein
the catalyst layer is continuously formed and a concave part that accepts the tip of the protective layer is formed in the catalyst layer, and
the tip of the protective layer is disposed in inside of the concave part.

5. The photoelectric conversion device according to claim 4, wherein
W_{c}≧Wₚ is satisfied when Wₚ is external width of the protective layer and W_{c} is width of the inside of the concave part.

6. The photoelectric conversion device according to claim 2, wherein
the catalyst layer is discontinuously formed in a strip manner on a plurality of columns, and
the tip of the protective layer is located between the catalyst layers that are adjacent to each other and are in the strip manner.

7. The photoelectric conversion device according to claim 6, wherein
W_{c}≧Wₚ is satisfied when Wₚ is external width of the protective layer and W_{c} is distance between the catalyst layers adjacent to each other.

8. The photoelectric conversion device according to claim 2, wherein
width of the oxide semiconductor layer is so decided that a value obtained by subtracting power loss due to resistive loss occurring in the whole of the oxide semiconductor layer from generated power arising in the whole of the oxide semiconductor layer is maximized.

9. A photoelectric conversion device module comprising:
a plurality of the photoelectric conversion devices including
a first substrate,
a collector layer configured to be provided over the first substrate,
a second substrate configured to be opposed to a planar surface of the first substrate and be formed of a metal having a concave notch part at one side, and
a connection terminal configured to be connected to the collector layer,
the connection terminal being disposed opposed to the concave notch part, configured to be disposed in a plane, wherein
the connection terminal of one of two photoelectric conversion devices adjacent to each other and the second substrate of the other are electrically connected to each other.
